(19) United States
(12) Patent Application Publication
(10) Pub. No.: US 2025/0293482 A1
(43) Pub. Date: Sep. 18, 2025

(54) SYSTEM AND METHOD FOR PHASE LOCKING LASERS WITH DIVERSE WAVELENGTHS

(71) Applicant: OEWAVES, INC., Pasadena, CA (US)

(72) Inventors: Lute MALEKI, Pasadena, CA (US); Yu-Hung LAI, Pasadena, CA (US)

(21) Appl. No.: 19/073,418

(22) Filed: Mar. 7, 2025

Related U.S. Application Data
(60) Provisional application No. 63/564,909, filed on Mar. 13, 2024.

(51) Int. Cl. H01S 5/14; H01S 5/065

(52) U.S. Cl. CPC H01S 5/142; H01S 5/0657

(57) ABSTRACT

A photonic system is described that employs, e.g., a first laser generating a first optical beam at a first wavelength and a second laser generating a second optical beam at a second, different wavelength. The photonic system also includes a resonator, e.g., a whispering gallery mode (WGM) resonator, configured to receive a portion of the first optical beam and a portion of the second optical beam. The first laser is locked to a first mode of the resonator using either self-injection locking (SIL) or Pound-Drever-Hall (PDH) locking. The second laser is also locked to a second mode of the resonator using either SIL or a PDH. The first and second wavelengths (frequencies) may differ from one another by a few gigahertz (GHz) or, e.g., larger than 10 terahertz (THz). The system thus allows diverse wavelengths to be locked to one another.

### PRIORITY CLAIM AND CROSS-REFERENCE TO RELATED APPLICATION

This patent document claims the priority of U.S. Provisional Application No. 63/564,909, entitled “SYSTEM AND METHOD FOR PHASE LOCKING LASERS WITH DIVERSE WAVELENGTHS,” filed on Mar. 13, 2024, the entire disclosure of which is incorporated by reference herein.

### FIELD OF THE DISCLOSURE

Various aspects of the disclosure relate to photonic systems.

### BACKGROUND

In many photonic applications related to metrology and quantum technology, lasers of widely separated (diverse) wavelengths (large frequency difference) must be phase locked together. In typical conventional techniques, an optical frequency comb (itself stabilized to a reference frequency) is used to lock each of the lasers to comb harmonics (one for each laser) at a wavelength closest to the laser wavelength. Since all harmonics of a frequency comb are phase coherent, the technique phase locks the lasers. However, techniques utilizing an optical frequency comb tend to be complex and expensive.

A new approach is needed to solve these and other problems.

### SUMMARY

In one aspect, an optical system is provided that includes: a first laser configured for generating a first optical beam at a first wavelength; a second laser configured for generating a second optical beam at a second, different wavelength; and a resonator configured for receiving a portion of the first optical beam and a portion of the second optical beam, with the first laser locked to a first mode of the resonator using either self-injection locking (SIL) or Pound-Drever-Hall (PDH) locking, and with the second laser locked to a second mode of to the resonator using either SIL or PDH locking.

In another aspect, a method is provided that includes: generating a first optical beam at a first wavelength using a first laser; generating a second optical beam at a second, different wavelength using a second laser; and routing a portion of the first optical beam and a portion of the second optical beam through a resonator while locking the first laser locked to a first mode of the resonator using either SIL or PDH locking, and while locking the second laser to a second mode of to the resonator using either SIL or PDH locking.

In yet another aspect, an apparatus is provided that includes: means for receiving a first optical beam at a first wavelength from a first laser; means for receiving a second optical beam at a second, different wavelength from a second laser; and means for routing a portion of the first optical beam and a portion of the second optical beam through a resonator while locking the first laser to a first mode of the resonator using either SIL or PDH locking, and while locking the second laser to a second mode of to the resonator using either SIL or PDH locking.

### BRIEF DESCRIPTION OF THE DRAWINGS

FIG. 1 is a block diagram of an exemplary photonic system that provides both self-injection locking (SIL) and Pound-Drever-Hall (PDH) locking to lock two lasers to two modes of the same cavity to stabilize the lasers to the level of stability of the cavity, in accordance with some aspects of the disclosure.

FIG. 2 is a block diagram of an exemplary photonic system that uses SIL to lock two lasers to two modes of the same cavity to stabilize the lasers to the level of stability of the cavity, in accordance with some aspects of the disclosure.

FIG. 3 is a block diagram of an exemplary photonic system that uses PDH to lock two lasers to two modes of the same cavity to stabilize the lasers to the level of stability of the cavity, in accordance with some aspects of the disclosure.

FIG. 4 is a block diagram of an exemplary system that uses either SIL or PDH to lock two lasers to two modes of the same resonator, in accordance with some aspects of the disclosure.

FIG. 5 is a flow diagram illustrating a method for locking two lasers to two modes of the same resonator using either SIL or PDH, in accordance with some aspects of the disclosure.

FIG. 6 is a flow diagram illustrating another method for locking two lasers to two modes of the same resonator using either SIL or PDH, in accordance with some aspects of the disclosure.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. In the figures, elements may each have a same reference number or a different reference number to suggest that the elements represented could be different and/or similar. However, an element may be flexible enough to have different implementations and work with some or all of the systems shown or described herein. The various elements shown in the figures may be the same or different and, which one is referred to as a first element and which is called a second element is arbitrary.

### Overview

Diverse fields of photonics, such as photonics metrology and quantum technology, often require phase locking of two or more lasers with wavelength differences larger than the frequency of RF references (e.g., an RF oscillator). Two lasers separated in wavelength (frequency) by an RF frequency can be made to create a beat frequency on a fast photodetector. The beat frequency is mixed with a reference frequency generated by an RF source. The output, which is amplified and filtered (e.g., using a phase lock loop, PLL), is used to control the frequency of one of the lasers so it follows the frequency of the other laser. In this scheme, the two lasers are phased locked within the locking bandwidth of the PLL. This technique can be extended to lock multiple lasers together if the same RF source can be used.

While generally effective, the aforementioned techniques cannot be applied to lasers with frequency (wavelength) difference that exceed the frequencies that are commonly synthesized using RF sources. For example, the frequency difference of a laser at 1550 nanometer (nm) with a laser at 1000 nm is more than 100 terahertz (THz). RF frequency references with this high a frequency are not commonly available.

The availability of commercial and laboratory optical frequency combs makes it possible to overcome the above limitation. An optical frequency comb consists of a large number of frequency (wavelength) harmonics that are separated by a fixed frequency (the so called free spectral range, FSR) from each other. These harmonics are phase locked together, as well. A comb may span hundreds of THz and octave spanning combs are commercially available. So, any two (or more) lasers with frequency (wavelength) differences that are within the comb span can be locked to each other by locking each one to a comb harmonic nearest in wavelength (frequency) to each laser. In this manner, the beat between each of the lasers and their corresponding comb harmonic will be at a manageably small frequency and so the phase locking technique with a reference RF oscillator described above may be used. Since every laser is phase locked to a comb harmonic and all comb harmonics are phase locked together, the lasers become phase locked to each other. This system thus provides for effective phase locking of lasers with diverse wavelengths (frequencies).

The main challenge with the comb locking scheme is its complexity. First, a typical frequency comb is a large, complex, and relatively expensive instrument. Often it is necessary to lock the comb itself separately to an optical reference, such as a reference laser locked to a stable atomic transition. Then locking of the lasers to the comb compounds the complexity, which in turn makes the scheme more complex.

An optical resonator has modes that are separated in frequency by a fixed interval (the free spectral range, FSR). The FSR of a cavity has a fixed value, and thus the modes may be regarded as a “passive” replica of frequency harmonics of the frequency comb. Therefore, locking two lasers to two modes of the same cavity will stabilize them to the level of stability of the cavity. Importantly, phase locking the lasers to the same cavity will also keep them phase locked within the bandwidth of the locking loop. As in the case of the comb stabilization, the cavity can be stabilized to, for example, an atomic reference to impart reference's stability to the lasers. Moreover, one of the lasers can be stabilized to an atomic reference or a reference laser and used to lock the resonator to the atomic reference or a reference laser. Then the second laser locked to the resonator will be phased locked to the atomic reference, as with all other lasers locked to the resonator. Otherwise, the resonator can be temperature stabilized and placed in a vacuum enclosure to be passively frequency stabilized. The lasers locked to the cavity will then be stabilized at the level of stability of the resonator.

This technique can be implemented with all suitable cavities. However, applying the technique with whispering gallery mode (WGM) resonators, ring resonators, or any open resonator (as opposed to those having mirrors, such as Fabry-Perot resonators) has particular benefits. WGM, ring, and similar resonators (cavities) support any wavelength within their transparency window, so lasers with diverse (widely separate) wavelengths can be phased locked together. This is important since locking with a comb requires the laser frequency (wavelength) to coincide with a comb harmonic frequency (wavelength) and also limits the difference in the wavelength (frequency) of the lasers to the comb frequency span, which typically is only one octave. For example, for two lasers with wavelengths one in the UV region and one in the Mid-IR region, the use of a frequency comb for phase locking them together is practically not usually possible. By contrast, many WGM resonators made with crystalline material, such as calcium fluoride and magnesium fluoride, support wavelengths in the UV and mid-IR. Importantly, WGM and ring resonators have modes with narrow bandwidth as a result of their high-quality factor (Q). This allows a tighter relative lock of the two lasers. Also, in some examples, lasers can be injection locked to modes of these resonators, eliminating the needed electronics as in a Pound-Drever-Hall (PDH) scheme. Finally, WGM and ring resonators can be implemented on and with photonic integrated circuits (PICs) containing the lasers to provide chip scale systems with miniaturized size, low power consumption, and low cost when produced in volume.

In view of the foregoing, in some aspects, an optical or photonic device is provided that includes: a first laser (or other suitable optical source) configured for generating a first optical beam at a first wavelength; a second laser (or other suitable optical source) configured for generating a second optical beam at a second, different wavelength; and a resonator (e.g., a WGM or ring resonator) configured for receiving a portion of the first optical beam and a portion of the second optical beam, with the first laser locked to a first mode of the resonator using common locking schemes such as SIL or PDH locking, and with the second laser locked to a second mode of to the resonator using either SIL or PDH locking. In one example, both optical sources are locked using SIL. In another example, both optical sources are locked using PDH. In yet another example, one of the optical sources is locked using SIL while the other is locked using PDH. Each approach provides its own benefit, depending on the lasers' characteristics. In some examples, a difference between the first wavelength (frequency) and the second wavelength (frequency) is in the range of a fraction of nanometer to many hundreds of nanometers or larger, as in the difference between an IR laser and a UV laser. In some examples, one wavelength (frequency) is in the UV range while the other wavelength (frequency) is in the mid-IR range.

It should be noted that while the above description applies to a pair of lasers, multiple lasers may be phase locked to each other using the approach. Thus, while the primary examples described herein have two mutually locked, it should be understood that the same approach can be applied to three or more lasers. The complete device or a part thereof may be realized on a photonic integrated circuit (PIC). In some examples, the PIC is configured to receive optical signals from lasers that are separate from the PIC, i.e., a user of the PIC provides the optical signals. In other examples, the PIC includes the lasers, thus providing a complete self-contained device.

### Exemplary Methods and Apparatus

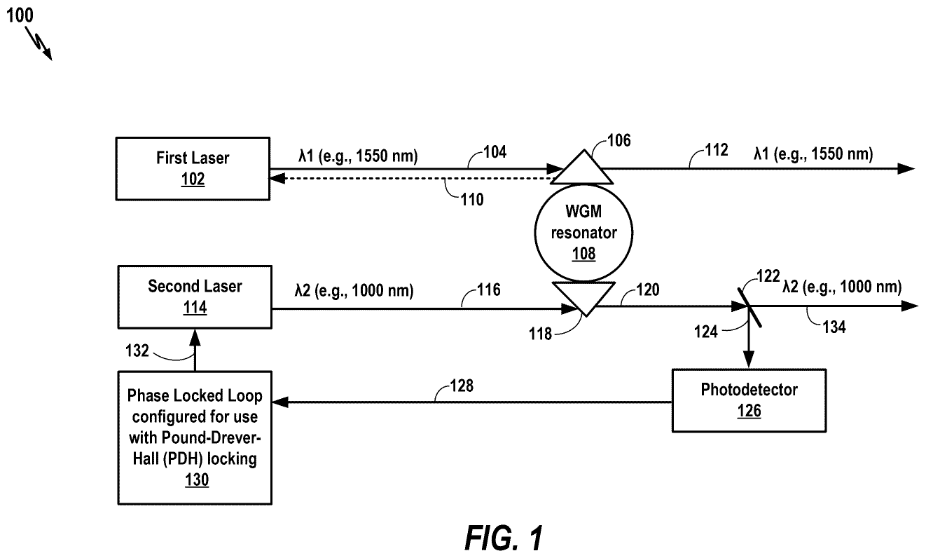

FIG. 1 is a block diagram of a photonic system, device or apparatus 100 that includes provides both SIL and PDH locking to lock two lasers to two modes of the same cavity to stabilize the lasers to the level of stability of the cavity.

A first laser 102 generates a laser beam 104 at a first wavelength of λ1 (e.g., 1550 nm), which is directed into an optical coupler 106 that feeds a portion of the beam 104 into a WGM resonator 108. A portion of the beam circulating within the resonator (not shown within the resonator) is then radiated back to the first laser 102 as a feedback beam 110. This configuration serves to self-injection lock the first laser 102 to its wavelength to λ1 (e.g., 1550 nm) by locking the first laser 102 to a first mode of the resonator 108. A portion of laser beam 104 also passes through optical coupler 106 to become a first output beam 112, which is thus also locked to λ1 (e.g., 1550 nm).

Concurrently, a second laser 114 generates the second laser beam 116 at a different wavelength of λ2 (e.g., 1000 nm). Laser beam 116 is directed into an optical coupler 118 which feeds a portion of beam 116 into the WGM resonator 108. A portion of the beam passing through optical coupler 118 emerges as beam 120, and a portion of that beam reflects off a half-silvered mirror 122 (or similar beam splitter) as beam 124, which is detected by a photo detector at 126. Photodetector 126 generates an electrical output signal 128, which is applied to a PLL 130 that is configured for use with PDH locking to generate a control signal 132, which controls the second laser 114. In this manner, the second laser 114 is PDH locked to its wavelength, λ2 (e.g., 1000 nm) by locking the second laser 114 to a second mode of the resonator 108. An output beam 134, passing through the half silver mirror or other optical beam splitter 122, is likewise locked to λ2 (e.g., 1000 nm).

Insofar as PDH is concerned, PDH locking is a well-known scheme used for laser stabilization and hence will not be described in detail herein. PDH may be implemented in various ways, but in general PDH is based on modulating the laser light before the resonator to produce an error signal which is fed-back to the laser. This may be achieved by detecting the reflected (or sometimes transmitted) modulation and feeding it back to the laser with the help of a suitably configured PLL. The PLL may be implemented in different ways by incorporating different components. In some aspects, PDH locking includes monitoring the derivative of a cavity transmission with respect to detuning between the laser frequency and the resonator mode, and that functionality may be incorporated into PLL 130. Note also that, although SIL feedback is provided by WGM resonator 108 to first laser 102 (via feedback beam 110), similar SIL feedback is not provided from WGM resonator 108 to the second laser 114 since PDH locking is instead employed. It is easy to arrange the device so that the second laser 114 is not self-injection locked. For example, an isolator may be used.

The WGM resonator 108 may be made with a crystalline material, e.g., an optically transparent material such as magnesium fluoride, calcium fluoride, lithium niobite, silicon and silicon nitride, to support wavelengths in the UV and mid-IR. As explained above, WGM have modes with narrow bandwidth as a result of their high-quality factor (Q). This allows a tighter relative lock of the two lasers 102 and 114.

Thus FIG. 1 illustrates an optical system that provides self-injection locking (SIL) of a first laser and PDH locking of a second laser at a significantly different wavelength. By feeding portions of both laser beams into the same WGM resonator, the lasers are by mutually locked to their respective wavelengths. As explained above, locking two lasers to two modes of the same cavity stabilize the lasers to the level of stability of the cavity. Phase locking the lasers to the same cavity also keeps the laser beams phase locked within the bandwidth of the locking loop. Although not shown in FIG. 1, the resonator cavity could be stabilized to a frequency reference to impart the reference's stability to the lasers, or passively frequency stabilized through temperature stabilization and placement in an evacuated enclosure. Note that the choice of 1550 nm and 1000 nm is merely illustrative. The two lasers could be, e.g., at 400 nm and 2000 nm, depending on the transparency window of the resonator material. While not shown in FIG. 1, multiple lasers may be locked together in this way. In some examples, the first and second lasers 102 and 114 are separate from a PIC that includes the other components, i.e., a user of the PIC provides the optical signals. In other examples, the PIC includes the lasers 102 and 114, thus providing a complete self-contained device.

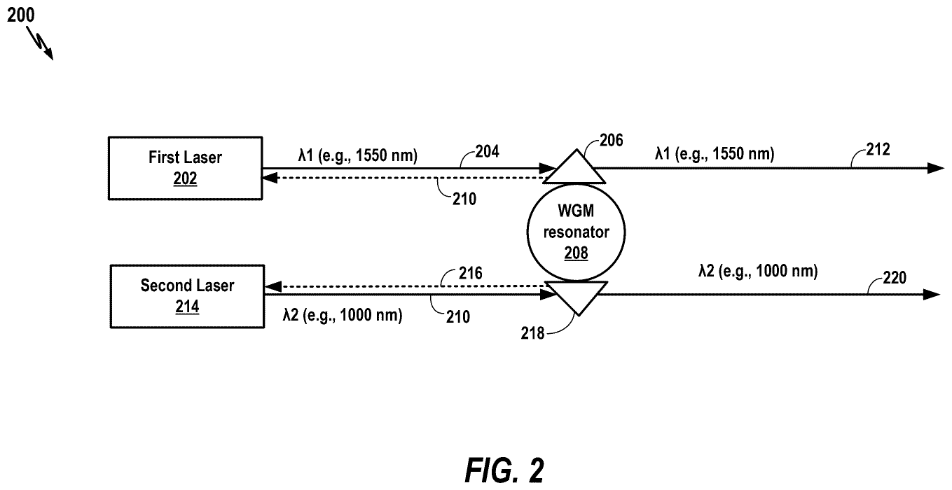

FIG. 2 is a block diagram of a photonic system, device or apparatus 200 that is similar to the system of FIG. 1 but uses SIL to lock both lasers.

A first laser 202 generates a laser beam 204 at a first wavelength of λ1 (e.g., 1550 nm), which is directed into an optical coupler 206 that feeds a portion of the beam 204 into a WGM resonator 208. A portion of the beam circulating within the resonator (not shown within the resonator) is then radiated back to the first laser 202 as a feedback beam 210. This configuration serves to self-injection lock the first laser 202 to its wavelength to λ1 (e.g., 1550 nm) by locking the first laser 202 to a first mode of the resonator 208. A portion of laser beam 204 also passes through optical coupler 206 to become a first output beam 212, which is thus also locked to λ1 (e.g., 1550 nm).

Concurrently, a second laser 214 generates the second laser beam 216 at a different wavelength of λ2 (e.g., 1000 nm). Laser beam 216 is directed into an optical coupler 218, which feeds a portion of beam 216 into the WGM resonator 208. A portion of the beam circulating within the resonator (not shown within the resonator) is then radiated back to the second laser 214 as a feedback beam 216. This configuration also serves to self-injection lock the second laser 214 to its wavelength λ2 (e.g., 1000 nm) by locking the second laser 214 to a second mode of the resonator 208. A portion of laser beam 210 also passes through optical coupler 218 to become a second output beam 220, which is thus also locked to λ2 (e.g., 1000 nm).

Thus FIG. 2 illustrates an optical system that provides self-injection locking of both a first laser and a second laser, with the two lasers at significantly different wavelengths. As with FIG. 1, by feeding portions of both laser beams into the same WGM resonator, the lasers are by mutually locked at their respective wavelengths. While not shown in FIG. 2, multiple lasers may be locked together in this way. In some examples, the first and second lasers 202 and 214 are separate from a PIC that includes the other components, i.e., a user of the PIC provides the optical signals. In other examples, the PIC includes the lasers 202 and 214, thus providing a complete self-contained device.

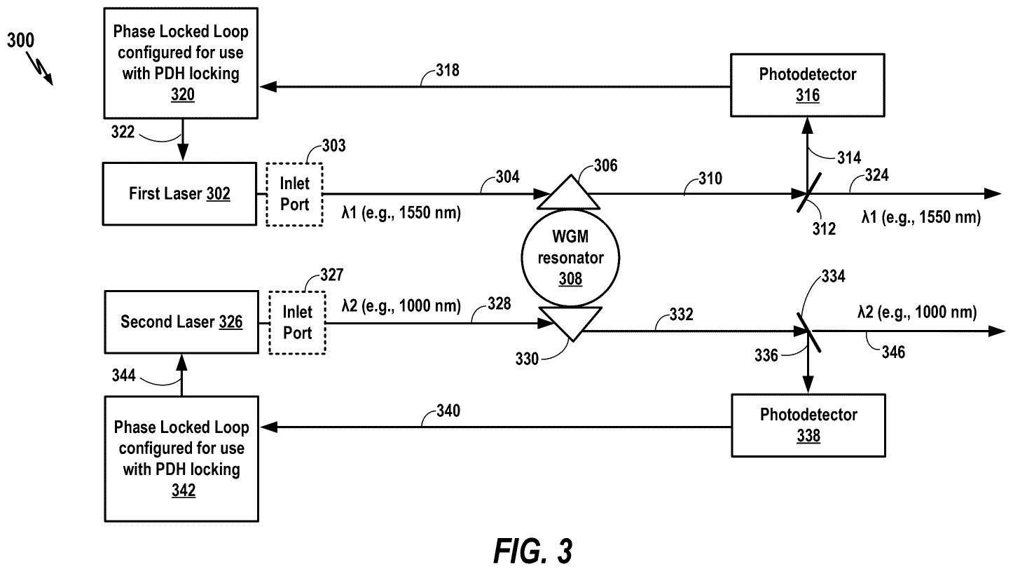

FIG. 3 is a block diagram of a photonic system, device or apparatus 300 that is similar to the system of FIGS. 1 and 2 but uses PDH to lock both lasers. A first laser 302 generates a first laser beam 304 at a first wavelength of λ1 (e.g., 1550 nm). In examples where the laser 302 is separate from the other components of the photonic device, an inlet port 303 of the photonic device may be provided to receive the laser beam. Laser beam 304 is directed (e.g., via a fiber optic or other suitable component) into an optical coupler 306, which feeds a portion of beam 304 into the WGM resonator 308. A portion of the beam passing through optical coupler 306 emerges as beam 310, and a portion of that beam reflects off a half-silvered mirror 312 (or similar beam splitter) as beam 314, which is detected by a photo detector 316. Photo detector 316 generates an electrical output signal 318, which is applied to a first PLL 320 to generate a control signal 322, which controls the first laser 302. In this manner, the first laser 302 is PDH locked to its wavelength, λ1 (e.g., 1550 nm) and an output beam 324, passing through the half silver mirror 312, is likewise locked to λ1.

Concurrently, a second laser 326 generates the second laser beam 328 at a different wavelength of λ2 (e.g., 1000 nm). In examples where the laser 326 is separate from the other components of the photonic device, an inlet port 327 of the photonic device may be provided to receive the laser beam. Laser beam 328 is directed (e.g., via a fiber optic or other suitable component) into an optical coupler 330, which feeds a portion of beam 328 into the WGM resonator 308. A portion of the beam passing through optical coupler 330 emerges as beam 332, and a portion of that beam reflects off a half-silvered mirror 334 (or similar beam splitter) as beam 336, which is detected by a photo detector at 338. Photo detector 338 generates an electrical output signal 340, which is applied to a PLL 342 to generate a control signal 344, which controls the second laser 326. In this manner, the second laser 325 is also PDH locked to its wavelength, λ2 (e.g., 1000 nm) and an output beam 346, passing through the half silver mirror 334, is likewise locked to λ2 (e.g., 1000 nm).

While not shown in FIG. 3, multiple lasers may be locked together in the same manner. In some examples, the first and second lasers 302 and 326 are separate from a PIC that includes some or all of the other components, i.e., a user of the PIC provides the optical signals. In other examples, the PIC includes the lasers 302 and 326, thus providing a complete self-contained device.

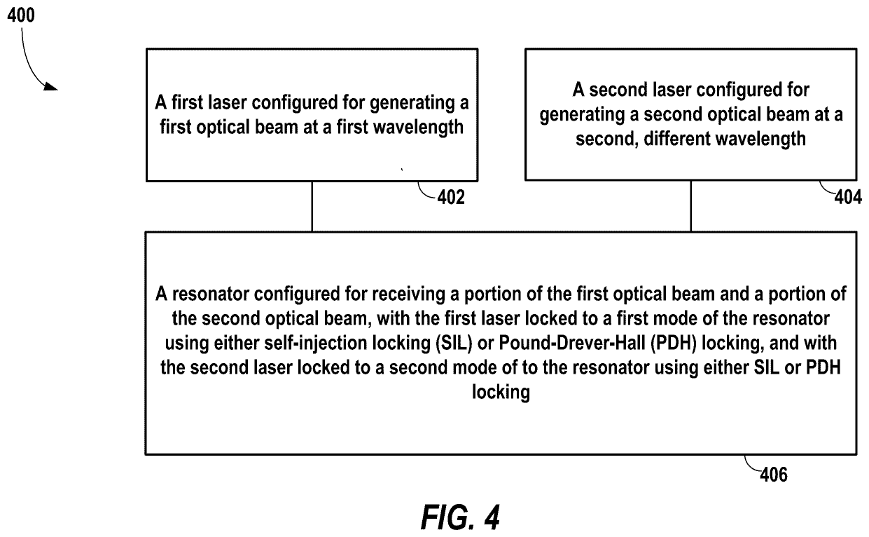

FIG. 4 illustrates an optical system 400. A first laser 402 is configured for generating a first optical beam at a first wavelength. A second laser 404 is configured for generating a second optical beam at a second, different wavelength. A resonator 406 is configured for receiving a portion of the first optical beam and a portion of the second optical beam, with the first laser locked to a first mode of the resonator using either SIL or PDH locking, and with the second laser locked to a second mode of to the resonator using either SIL or PDH locking. While not explicitly shown in FIG. 4, multiple lasers may be locked together in the same manner. For example, optical system 400 may include one or more additional lasers configured for generating additional optical beams at additional wavelengths that are different from one another and from the first and second wavelengths. The resonator may be further configured for receiving portions of the additional optical beams, with the additional lasers locked to additional modes of the resonator using either SIL or PDH locking. All or a portion of the optical system of FIG. 4 may be implemented as a PIC (including the lasers) to provide chip scale systems with miniaturized size, low power consumption, and low cost when produced in volume.

In some aspects, the first laser 402 of FIG. 4 provides a means for generating a first optical beam at a first wavelength. See, also, lasers 102 and 202. The second laser 404 provides a means for generating a second optical beam at a second, different wavelength. See, also, lasers 114 and 214. The resonator 406 provides a means for receiving a portion of the first optical beam and a portion of the second optical beam, with the means for generating a first optical beam (e.g., the first laser) locked to a first mode of the resonator using either SIL or PDH locking, and with the means for generating a second optical beam (e.g., the second laser) locked to a second mode of to the resonator using either SIL or PDH locking. See, also, resonators 108 and 208.

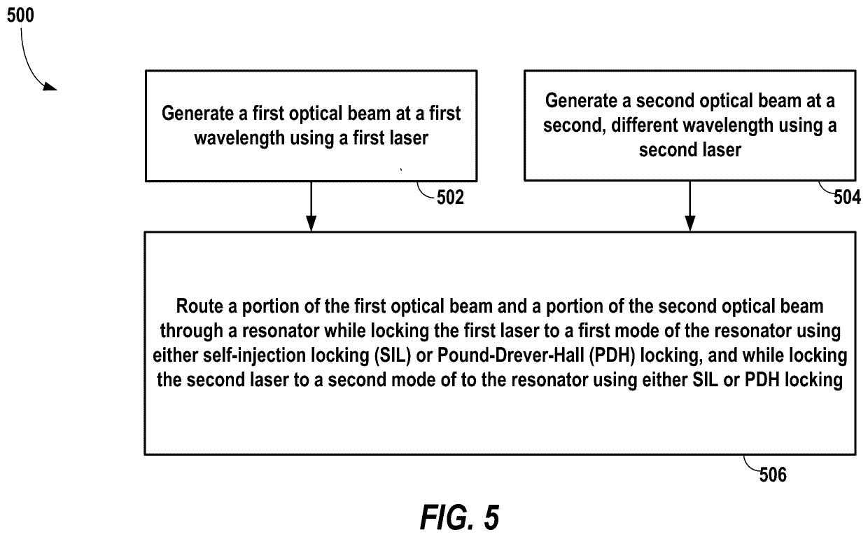

FIG. 5 illustrates a method 500 that may be performed by the photonic systems of FIG. 1, 2, 3, or 4 or by other suitably-equipped systems, devices, or apparatus. Briefly, at 502, the photonic system generates a first optical beam at a first wavelength using a first laser. Concurrently, at 504, the photonic system generates a second optical beam at a second, different wavelength using a second laser. At block 506, the photonic system routes a portion of the first optical beam and a portion of the second optical beam through a resonator while locking the first laser to a first mode of the resonator using either SIL or PDH locking, and while locking the second laser to a second mode of to the resonator using either SIL or PDH locking. The method of FIG. 5 may be performed, for example, by a PIC that includes lasers to function as a self-contained apparatus. While not explicitly shown in FIG. 5, multiple lasers may be locked together in the same manner. For example, the method may include generating additional optical beams at additional wavelengths that are different from one another and from the first and second wavelengths, and then routing additional portions of the additional optical beams through the resonator, with the additional lasers locked to additional modes of the resonator using either SIL or PDH locking.

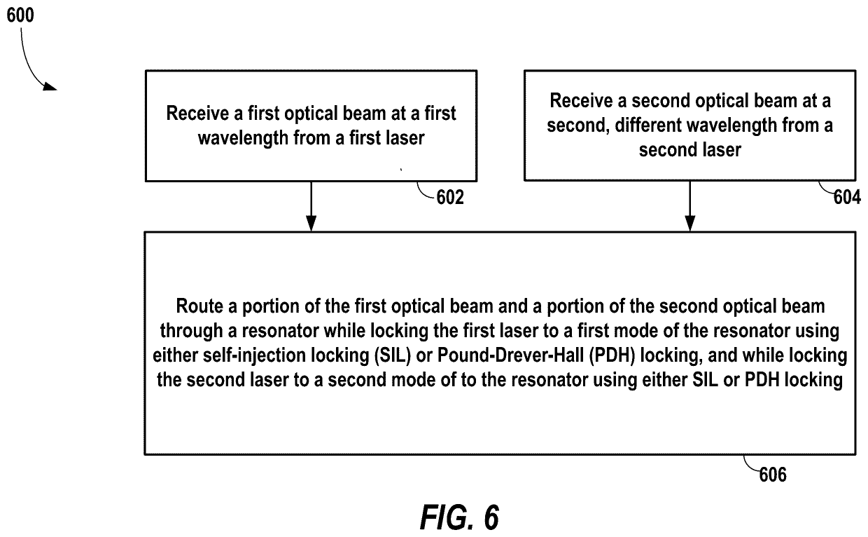

FIG. 6 illustrates a method 600 that may be performed by the photonic systems of FIG. 1, 2, 3, or 4 or by other suitably-equipped systems, devices, or apparatus. Briefly, at 602, the photonic system receives a first optical beam at a first wavelength from a first laser. Concurrently, at 604, the photonic system receives a second optical beam at a second, different wavelength from a second laser. At block 606, the photonic system routes a portion of the first optical beam and a portion of the second optical beam through a resonator while locking the first laser to a first mode of the resonator using either SIL or PDH locking, and while locking the second laser to a second mode of to the resonator using either SIL or PDH locking. The method of FIG. 6 may be performed, for example, by a PIC that received laser beams from a separate user apparatus. While not explicitly shown in FIG. 6, multiple lasers may be locked together in the same manner. For example, the method may include generating additional optical beams at additional wavelengths that are different from one another and from the first and second wavelengths, and then routing additional portions of the additional optical beams through the resonator, with the additional lasers locked to additional modes of the resonator using either SIL or PDH locking.

In some aspects, an apparatus is provided that includes: means for receiving a first optical beam at a first wavelength from a first laser; means for receiving a second optical beam at a second, different wavelength from a second laser; and means for routing a portion of the first optical beam and a portion of the second optical beam through a resonator while locking the first laser locked to a first mode of the resonator using either self-injection locking (SIL) or Pound-Drever-Hall (PDH) locking, and while locking the second laser to a second mode of to the resonator using either SIL or PDH locking.

In some aspects, the means for receiving the first optical beam may be a first input port of the photonic device (e.g., inlet port 303 of FIG. 3), which receives the first laser beam and routes the first laser beam to the optical coupler 306. In some aspects, the means for receiving the second optical beam may be a second input port of the photonic device (e.g., inlet port 327 of FIG. 3), which receives the second laser beam and routes the second laser beam to the optical coupler 330. In some aspects, the optical couplers 306 and 330 of FIG. 3 provide a means for routing a portion of the first optical beam and a portion of the second optical beam through a resonator while locking the first laser locked to a first mode of the resonator using either self-injection locking (SIL) or Pound-Drever-Hall (PDH) locking, and while locking the second laser to a second mode of to the resonator using either SIL or PDH locking. In some aspects, the PLLs of the figures (e.g., 130, 320, and 342) provide a means for PDH locking. The PLLs also provide a means for receiving an electrical output signal (e.g., along line 318) and for applying a phase-locked version of the electrical signal to a laser (e.g., along line 322) as a control signal to lock the laser to a mode of the resonator. In some aspects, the resonators of the figures (e.g., 108, 208, and 308) provide a means for resonating. The photodetectors of the figures (e.g., 126, 316, and 338) provide a means for photodetection or a means for receiving a portion of a optical beam and generating a corresponding electrical output signal. These are just some examples.

### ADDITIONAL ASPECTS AND CONSIDERATIONS

Note that one or more of the components, steps, features, and/or functions illustrated in FIGS. 1, 2, 3, 4, 5, and/or 6 may be rearranged and/or combined into a single component, step, feature or function or embodied in several components, steps, or functions. Additional elements, components, steps, and/or functions may also be added without departing from the invention.

The word “exemplary” is used herein to mean “serving as an example, instance, or illustration.” Any implementation or aspect described herein as “exemplary” is not necessarily to be construed as preferred or advantageous over other aspects of the disclosure. Likewise, an aspect is an implementation or example. Reference in the specification to “an aspect,” “one aspect,” “some aspects,” “various aspects,” or “other aspects” means that a particular feature, structure, or characteristic described in connection with the aspects is included in at least some aspects, but not necessarily all aspects, of the present techniques. The various appearances of “an aspect,” “one aspect,” or “some aspects” are not necessarily all referring to the same aspects. Elements or aspects from an aspect can be combined with elements or aspects of another aspect.

The term “coupled” may mean that two or more elements are in direct physical or electrical contact. However, “coupled” may also mean that two or more elements are not in direct contact with each other, but yet still co-operate or interact with each other.

Not all components, features, structures, characteristics, etc. described and illustrated herein need be included in a particular aspect or aspects. If the specification states a component, feature, structure, or characteristic “may,” “might,” “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Although some aspects have been described in reference to particular implementations, other implementations are possible. Additionally, the arrangement and/or order of elements or other features illustrated in the drawings and/or described herein need not be arranged in the particular way illustrated and described. Many other arrangements are possible according to some aspects.

Also, it is noted that the aspects of the present disclosure may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a function, a procedure, a subroutine, a subprogram, etc. When a process corresponds to a function, its termination corresponds to a return of the function to the calling function or the main function.

Those of skill in the art would further appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system.

The various features of the invention described herein can be implemented in different systems without departing from the invention. It should be noted that the foregoing aspects of the disclosure are merely examples and are not to be construed as limiting the invention. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. An optical system, comprising:
a first laser configured for generating a first optical beam at a first wavelength;
a second laser configured for generating a second optical beam at a second, different wavelength; and
a resonator configured for receiving a portion of the first optical beam and a portion of the second optical beam, with the first laser locked to a first mode of the resonator using either self-injection locking (SIL) or Pound-Drever-Hall (PDH) locking, and with the second laser locked to a second mode of to the resonator using either SIL or PDH locking.

2. The optical system of claim 1, wherein the first laser is locked to the first mode of the resonator using SIL, and the second laser is locked to the second mode of the resonator using SIL.

3. The optical system of claim 1, wherein the first laser is locked to the first mode of the resonator using SIL, and the second laser is locked to the second mode of the resonator using PDH locking.

4. The optical system of claim 1, wherein the first laser is locked to the first mode of the resonator using PDH locking, and the second laser is locked to the second mode of the resonator using PDH locking.

5. The optical system of claim 1, further comprising:
one or more additional lasers configured for generating additional optical beams at additional wavelengths that are different from one another and from the first and second wavelengths; and
wherein the resonator is further configured for receiving portions of the additional optical beams, with the additional lasers locked to additional modes of the resonator using either SIL or PDH locking.

6. The optical system of claim 1, wherein the resonator comprises an open resonator.

7. The optical system of claim 6, wherein the open resonator comprises a whispering gallery mode (WGM) resonator or a ring resonator.

8. The optical system of claim 1, wherein the resonator comprises a whispering gallery mode (WGM) resonator comprised of an optically transparent material.

9. The optical system of claim 1, wherein a difference between the first wavelength and the second wavelength corresponds to a frequency greater than 10 GHz.

10. The optical system of claim 1, wherein the first wavelength is at any value as short as UV and the second wavelength is at any value as large as IR.

11. The optical system of claim 1, wherein all or part of the optical system is formed on a photonic integrated circuit (PIC).

12. The optical system of claim 1, wherein the first laser is locked to the first mode of the resonator using PDH locking, and wherein the optical system further comprises:
a photodetector configured to receive a portion of the first optical beam as output from the resonator and generate a corresponding electrical output signal; and
a phase-locked loop (PLL) component configured to receive the electrical output signal from the photodetector and apply a phase-locked version of the electrical signal to the first laser as a control signal to control the first wavelength to thereby lock the first laser to the first mode of the resonator using PLL locking.

13. A method for use with an optical system, the method comprising:
generating a first optical beam at a first wavelength using a first laser;
generating a second optical beam at a second, different wavelength using a second laser; and
routing a portion of the first optical beam and a portion of the second optical beam through a resonator while locking the first laser locked to a first mode of the resonator using either self-injection locking (SIL) or Pound-Drever-Hall (PDH) locking, and while locking the second laser to a second mode of to the resonator using either SIL or PDH locking.

14. The method of claim 13, wherein the first laser is locked to the first mode of the resonator using SIL and the second laser is locked to the second mode of the resonator using SIL.

15. The method of claim 13, wherein the first laser is locked to the first mode of the resonator using SIL and the second laser is locked to the second mode of the resonator using PDH locking.

16. The method of claim 13, wherein the first laser is locked to the first mode of the resonator using PDH locking and the second laser is locked to the second mode of the resonator using PDH locking.

17. The method of claim 13, further comprising:
generating additional optical beams at additional wavelengths that are different from one another and from the first and second wavelengths; and
routing additional portions of the additional optical beams through the resonator, with the additional lasers locked to additional modes of the resonator using either SIL or PDH locking.

18. The method of claim 13, wherein the resonator comprises an open resonator.

19. The method of claim 18, wherein the open resonator comprises a whispering gallery mode (WGM) resonator or a ring resonator.

20. The method of claim 13, wherein the resonator comprises a whispering gallery mode (WGM) resonator comprised of an optically transparent material.

21. The method of claim 13, wherein a difference between the first wavelength and the second wavelength corresponds to a frequency greater than 10 GHz.

22. The method of claim 13, wherein the first wavelength is in the UV wavelength range and the second wavelength is in the mid-IR wavelength range.

23. An apparatus comprising:
means for receiving a first optical beam at a first wavelength from a first laser;
means for receiving a second optical beam at a second, different wavelength from a second laser; and
means for routing a portion of the first optical beam and a portion of the second optical beam through a resonator while locking the first laser locked to a first mode of the resonator using either self-injection locking (SIL) or Pound-Drever-Hall (PDH) locking, and while locking the second laser to a second mode of to the resonator using either SIL or PDH locking.
